(19) United States
(12) Patent Application Publication
(10) Pub. No.: US 2005/0258983 A1
(43) Pub. Date: Nov. 24, 2005

(54) Method and apparatus for voice trans-rating in multi-rate voice coders for telecommunications

(75) Inventors: Marwan A. Jabri, Broadway (AU); Jianwei Wang, Killarney Heights (AU); Sameh Georgy, Riverwood (AU)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Dilithium Holdings Pty Ltd. (an Australian corporation), Broadway (AU)

(21) Appl. No.: 10/843,844

(22) Filed: May 11, 2004

(51) Int. Cl. H03M 7/00

(52) U.S. Cl. 341/50

(57) ABSTRACT

Method and apparatus for trans-rating a bitstream of data through multi-rate voice coders converting a bitstream representing frames of data encoded according to a first voice compression method of a first rate to a second voice compression method according to a second rate. A trans-rating pair includes voice compression parameters mapping modules. The method of trans-rating includes either bit-unpacking or unquantization on an encoded packet at input site to obtain rate information and voice compression parameters according to the first rate voice compression method. The information of the first rate and the required output rate, namely a second rate type, in addition to external control commands, are then used to determine the converting strategy of the trans-rating pair. Next, at least some of the compression parameters of the first rate are passed through, or mapped, into compression parameters of the second rate compatible with the second rate voice compression method.

### CROSS-REFERENCES TO RELATED APPLICATIONS

NOT APPLICABLE

### STATEMENT AS TO RIGHTS TO INVENTIONS MADE UNDER FEDERALLY SPONSORED RESEARCH OR DEVELOPMENT

NOT APPLICABLE

### REFERENCE TO A “SEQUENCE LISTING,” A TABLE, OR A COMPUTER PROGRAM LISTING APPENDIX SUBMITTED ON A COMPACT DISK.

NOT APPLICABLE

### BACKGROUND OF THE INVENTION

The present invention relates generally to processing telecommunication signals. More particularly, the invention relates to a method and apparatus for voice trans-rating from a first voice compression bitstream of one data rate encoding method to a second voice compression bitstream of a different data rate. Merely by way of example, the invention has been applied to voice trans-rating in multi-rate or multi-mode Code Excited Linear Prediction (CELP) based voice compression codecs, but it would be recognized that the invention may also include other applications.

Trans-rating is a digital signal processing technique used to bridge the gap between two terminals operating at different rates. This typically occurs when two or more terminals include a multi-rate voice codec such as a GSM-AMR codec that can operate under 8 different rates of active speech modes and SID and DTX frames for non-active speeches. When a GSM-AMR terminal operates at the highest rate of 12.2 kbps tries to communicate with another GSM-AMR terminal operating at a different rate, 4.95 kbps or other, trans-rating is needed.

One conventional trans-rating approach performs rate conversion through decoding the input bitstream into speech signals and then re-encoding the speech signals according to another rate voice compression method. This decoding and re-encoding procedure involve a significant amount of calculation which includes bit-unpacking to obtain voice compress parameters, reconstructing excitation signals, synthesizing a pulse-coded-modulated (PCM) format voice signals, post-filtering the voice signals, and analyzing the PCM speech signals again to obtain voice compression parameters and re-encoding the voice compression parameters such as LSP, adaptive codebook parameters, adaptive codebook gain, fixed-codebook index parameters and fixed-codebook gain according to the second rate voice coding method.

The conventional trans-rating process has a further disadvantage in that delay increases by at least one additional frame algorithm delay due to look-ahead in the re-encoding process.

Smart trans-rating is not the conventional way of decoding and re-encoding, but rather smart trans-rating operates in a completely different domain. Smart trans-rating performs the bitstream conversion restricted to the compression parameter domain. In many cases, some defined mathematical mapping for different rates is applied to the CELP parameter indices from the original bitstream to the destination bitstream. These parameters are applicable to the LPC, adaptive codebook parameters, adaptive codebook gain, fixed-codebook indices parameters and fixed-codebook gain parameters.

What is needed is a technique that overcomes the limitations of conventional trans-rating and effectively applies smart trans-rating principles.

### SUMMARY OF THE INVENTION

Accordingly, the present invention is directed to a multi-rate voice coder bitstream trans-rating apparatus and method for converting a first rate voice packet data to a second rate voice packet data, which employs an input bitstream unpacker, one or more trans-rating pairs, pass-through modules, configuration modules, and an output bitstream packer. Each trans-rating pair includes at least one voice compression parameters mapping module among modules for direct space domain mapping, analysis in excitation domain mapping, and analysis in filtered excitation domain mapping. Finally the apparatus includes modules for mixing part of the pass-through and part of the mapping. The method of trans-rating includes either bit-unpacking or unquantization on an encoded packet at the input site to obtain rate information and voice compression parameters according to the first rate voice compression method. The information on the first rate and the required output rate, namely a second rate type, in addition to external control commands, is then used to determine the converting strategy of the trans-rating pair. Next, part or all of the compression parameters of the first rate are passed through, or mapped into compression parameters of the second rate in a manner compatible with the second rate voice compression method.

The transformation approaches can be varied and further optimized based on the characteristics of the pair of first rate compression method and the second rate compression method. Lastly, the second rate voice compression parameters are packed into a bitstream that is compatible with the second rate of multi-rate voice coder standard.

An apparatus according to the invention includes for example:
a voice compression code parameter unpack module that extracts the input first rate voice packet according to the first rate voice codec compression method into the first rate information and its voice compressed parameters. In the case of CELP-based codecs, these parameters may be line spectral frequencies parameters, adaptive codebook parameters, adaptive codebook gain parameters, fixed codebook gain parameters and fixed codebook index parameters as well as other parameters;
a trans-rating controller module that takes input bitstream data rate or mode, input bitstream frame error flag, desired output bitstream data rate or mode, and external control command, and output the decision of output data rate or mode to generate the decision of trans-rating strategies;
at least of one trans-rating pair module that converts input speech parameters of first rate generating from source bitstream unpacker into the quantized speech parameters of the second rate codec;
at least of one pass-through module that which passes the input encoded parameters to the output encoded parameters directly if the output second rate codec is the same as the input first rate codec; and
a voice compression codec bitstream packer for grouping the converted and quantized speech parameters of the second rate into output bitstream packets.

The present invention has the following objectives:
To perform smart voice trans-rating between different voice codec rate bitstreams of multi-rate voice coders in a compressed voice parameter domain;
To improve voice quality through mapping parameters in parameter space;
To reduce the delay through the trans-rating process;
To reduce the computational complexity of the trans-rating process;
To reduce the amount of computer memory required by the trans-rating process;
To support pass-through features in either the same rate bitstream conversion, or in a different rate bitstream conversion but with the output bitstream of an output rate that can be deduced from input bitstream;
To provide a generic trans-rating architecture that can be adapted to current and future multi-rate voice codecs.

According to one aspect of the present invention, the trans-rating module apparatus further includes a decision module that is adapted to select a CELP parameter mapping strategy based upon a plurality of strategies, and at least one conversion module comprising:
A module for voice compression parameters direct space mapping that produces the destination data rate compression parameters using straight-forward analytical formulae without any iteration;
A module for analysis, in the excitation space domain, of mapping that produces the destination data rate compression parameters by performing a search in the excitation space domain;
A module for analysis, in the filtered excitation space domain, of mapping that produces the destination data rate compression parameters by searching adaptive codebook of closed-loop in the excitation space and fixed-codebook in the filtered excitation space;
A module for pass-through mixed mapping that mixes part of quantized parameter pass-through where part of the parameters of an input data rate bitstream have the same quantized value as the parameters of an output data rate bitstream.

The mapping module selected in a specific trans-rating pair can be pre-defined or be selected by the decision dynamically.

In another aspect of the present invention, a method for trans-rating a first rate bitstream to a second rate bitstream of multi-rate voice coders comprises the following steps:
Processing a header of an input first rate voice codec bitstream to identify the first rate or mode or wrong packet of the input codec bitstream;
Unpacking the input bitstream of the first rate codec to at least one set of voice compression parameters;
Configuring a trans-rating pair converting the first rate input bitstream to a demanded second rate codec output bitstream;
Converting the first rate of one or more voice encoded parameters to a second set of rate encoded compression parameters;
Passing directly through input one or more sets of encoded parameters to the output if quantization of voice compression parameters of the input first rate codec is the same as the output second rate codec;
Packing the output second rate encoded parameter set or sets into the output second rate codec bitstream.

It is to be understood that both the foregoing general description and the following detailed description are exemplary and explanatory and are intended to provide further explanation of the invention as claimed.

The present invention, both as to its organization and manner of operation, together with further objects and advantages, may best be understood by reference to the following description, taken in connection with the accompanying drawings.

### BRIEF DESCRIPTION OF THE DRAWINGS

FIG. 1 is a block diagram of a prior art process for illustrating trans-rating of a multi-rate voice coder.

FIG. 2 is a block diagram of a prior art system illustrating a general trans-rate connection to convert a bitstream from one codec rate bitstream to another rate bitstream through decoding and re-encoding processes.

FIG. 3 is a block diagram illustrating a general trans-rate connection to convert a bitstream from one codec rate bitstream to another rate bitstream without full decode and re-encode.

FIG. 4 is a table showing prior art Adaptive-Multi-Rate (AMR, and also called GSM-AMR) voice coder multi-rate bit allocation for each 20 ms frame.

FIG. 5 is a block diagram illustrating the voice trans-rating of a representative embodiment of the present invention.

FIG. 6 is a block diagram illustrating input bitstream unpacking including packet type detection and parameters unquantization.

FIG. 7 is a block diagram further illustrating parameters unquantization in a Code Excited Linear Prediction (CELP) based voice codec.

FIG. 8 is a block diagram illustrating a trans-rating module.

FIG. 9 is a block diagram illustrating the trans-rating process through direct CELP parameter space mapping.

FIG. 10 is a block diagram illustrating the trans-rating process through CELP excitation parameter space mapping.

FIG. 11 is a block diagram illustrating excitation vector calibration.

FIG. 12 is a block diagram illustrating the trans-rating process through CELP excitation parameter space and filtered excitation parameter space mapping.

FIG. 13 is a block diagram illustrating mixing modules of parameter pass-through and mapping.

FIG. 14 is a block diagram illustrating an example of trans-rating using a mix of parameter pass-through and mapping from rate 5.15 kbps to rate 4.75 kbps in AMR.

FIG. 15 is a block diagram illustrating an example of trans-rating using a mix of parameter pass-through and mapping from rate 4.75 kbps to rate 5.15 kbps in AMR.

FIG. 16 is a block diagram illustrating an example of trans-rating using analysis in filtered excitation method from rate 12.2 kbps to rate 4.75 kbps in AMR.

FIG. 17 is a block diagram illustrating an example of trans-rating using analysis in filtered excitation method from rate 4.75 kbps to rate 12.2 kbps in AMR.

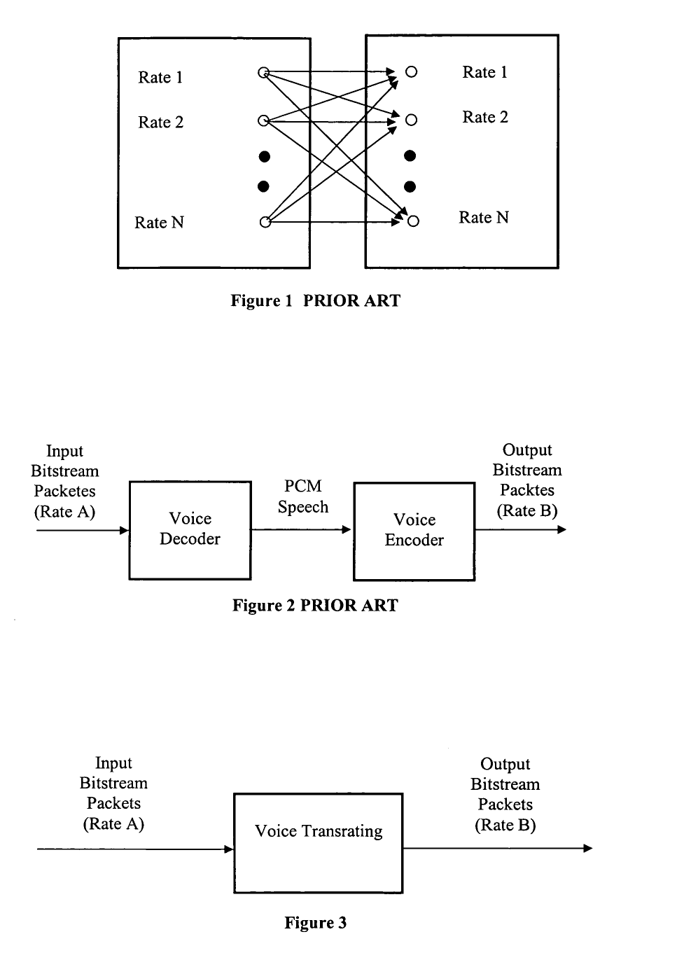

### DESCRIPTION SPECIFIC EMBODIMENTS OF THE INVENTION

In the following description, for purposes of explanation, numerous specific details are set forth in order to provide a thorough understanding of the present invention. The cases of multi-rate voice coder GSM-AMR different rates trans-rating are used as examples for illustration purposes. The methods described herein apply generally to trans-rating between any pair of multi-rate voice codecs. A person skilled in the relevant art will recognize that other steps, configurations and arrangements can be used without departing from the spirit and scope of the present invention.

The invention includes methods used to perform smart trans-rating between two codecs of different code rates in a multi-rate voice coder. The invention also includes a special case of trans-rating pass-through where the required output bitstream has the same rate codec as that of the input bitstream. The following sections discuss the details of the present invention

FIG. 5 is a block diagram illustrating a multi-rate voice coder trans-rating apparatus 10 according to a first embodiment of the present invention. The device comprises an input bitstream unpack module 12, a smart interpolation engine 14, including at least one trans-rating pair module 16, 18, 20, at least one pass-through module 22, together with a trans-rating control command module 24 controlling routing switches 26 and 28 and an output bitstream pack module 30. The apparatus 10 receives a first rate voice codec bitstream as an input to the input bitstream unpack module 12 and passes the result of rate information to the configuration control command module 24. The configuration control command module 24 takes input rate information, the desired output rate information and external network commands to decide a specific trans-rating pair module 16 or a pass-through module 22 and to control the switching of data flow from the input bitstream unpack module 12 to the output bitstream pack module 30. The trans-rating pair module 16 converts the input rate codec compressed parameters into the output rate codec quantized voice compressed parameters. The pass-through module 22 passes the input rate codec quantized parameters directly to output rate codec quantized parameters or even input bitstream packets directly. The output bitstream pack module 30 groups the converted and quantized output rate codec parameters into output bitstream packets.

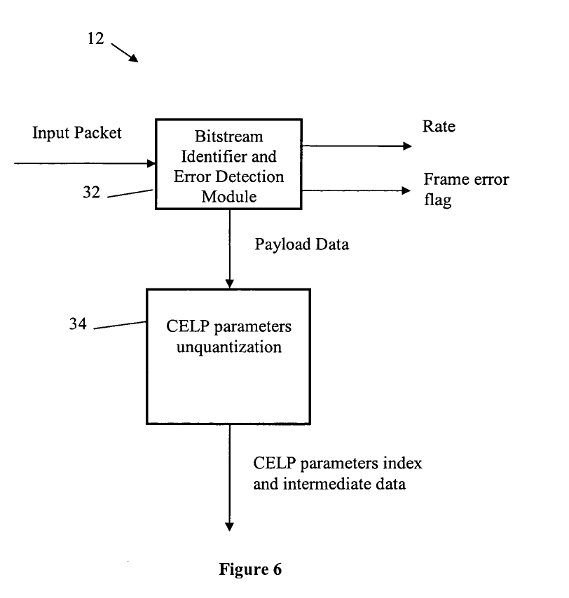

FIG. 6 illustrates a structure of an input bitstream unpack module 12 which comprises an input bitstream detection module 32 and a CELP compressed parameter unquantization module 34. The bitstream identifier module 32 performs rate information interpolation and error detection. It outputs the data rate information of the bitstream and passes the payload of the bitstream to voice a compressed parameters unquantization module (not shown). If there is an error detected in the bitstream, the module 32 sends out the frame error flag.

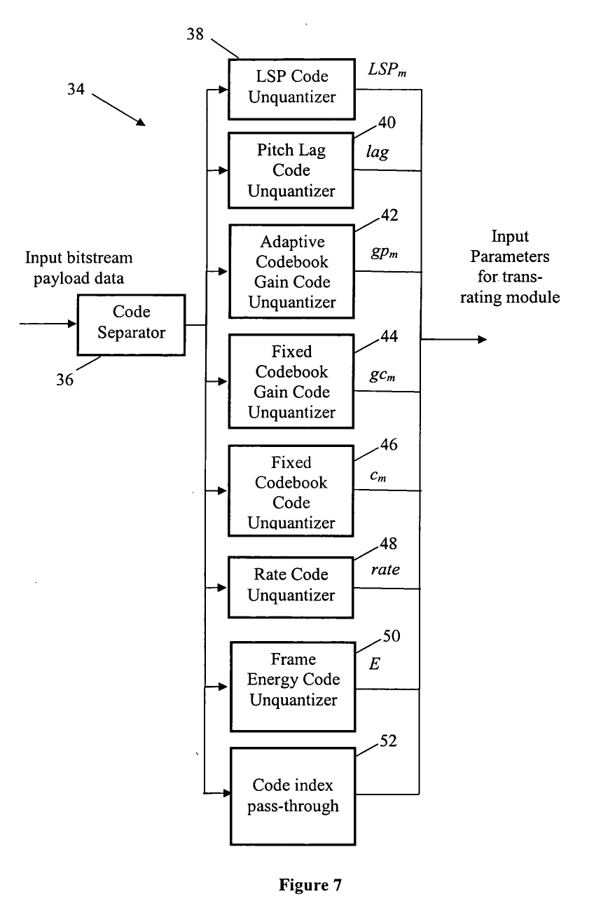

FIG. 7 further illustrates a block diagram of CELP based voice compressed parameters unquantization module 34 in the input bitstream unpack module 12. The unquantization module 34 comprises a code separator unit 36 and different compression parameter unquantizer units, namely an LSP unquantizer 38, a pitch lag code unquantizer 40, an adaptive codebook gain code unquantizer 42, a fixed codebook gain code unquantizer 44, a fixed codebook code unquantizer 46, a rate code unquantizer 48, a frame energy code unquantizer 50, and a code index pass through 52. The unquantizers are respectively applied to separate the bitstream payload code for each frame into a LSP code, a pitch lag code, and adaptive codebook gain code, a fixed codebook gain code, a fixed codebook vector code, a rate code, and a frame energy code, each choice based on the encoding method of the source codec. The actual parameter codes available depend on the codec itself, the bit-rate, and if applicable, the frame type. These codes are input into the appropriate code unquantizers, which output, respectively, the LSPs, pitch lag(s), adaptive codebook gains, fixed codebook gains, fixed codebook vectors, rate, and frame energy. Often more than one value is available at the output of each code unquantizer due to the multiple subframe excitation processing used in many CELP coders. The CELP parameters for the frame are then input to next stages.

The trans-rating control module receives the packet type and data rate of the input bitstream, and the external control commands of the output of the second codec rate, as shown in FIG. 5. It controls the switching modules to select one of trans-rating pair modules based on the input bitstream and output rate requirements. It is possible to select pass-through modules if the required output rate is the same as input bitstream rate. For example, if an input bitstream is a silence description frame type, and the type and format of the silence description are the same for the required output rate codec, the trans-rating control module will select pass-through module to perform silence description frames during the trans-rating process.

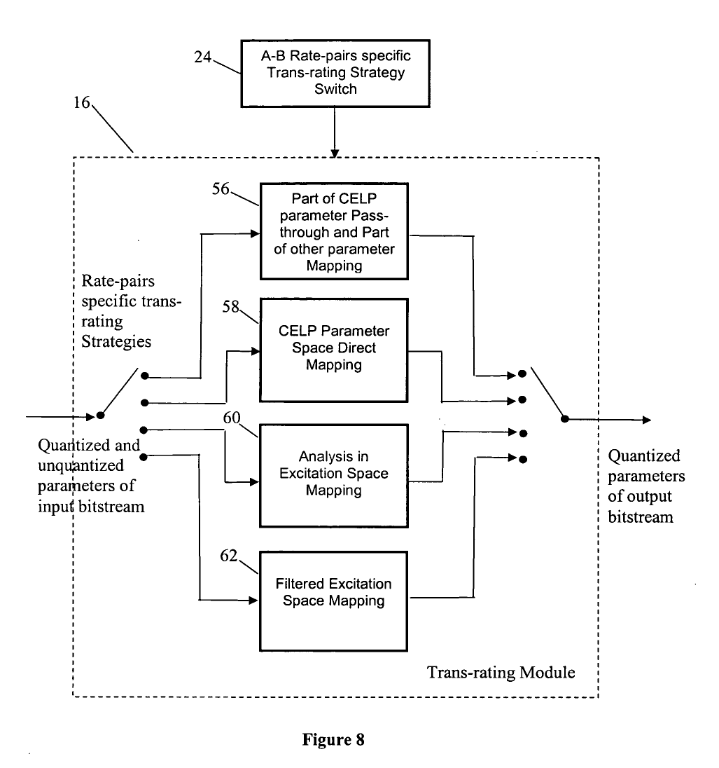

FIG. 8 illustrates a structure of a trans-rating pair module 16 which performs the specific rate conversion. Several mapping approaches may be used, including an element 56 using mix pass-through part of input rate codec quantized parameters to output rate code parameters and mapping other part of parameters; an element 58 for direct mapping from input rate codec unquantized parameters to the corresponding output rate codec parameters without any further analysis or iterations; an element 60 for analysis in the excitation domain; and an element 62 for analysis in the filtered excitation domain or a combination of these strategies, such as searching an adaptive codebook (not shown) in the excitation space and a fixed-code codebook (not shown) in the filtered excitation space. These four types of mapping are controlled by a trans-rating decision strategy viewed as a switch control unit 24 inside the module 16.

The trans-rating control command module 24 (FIG. 5), also known as a strategy decision module 24 (FIG. 8), determines which mapping strategy is to be applied. The decision may be pre-defined based on the characteristics of the similarities and differences between the specific input rate and output rate codec trans-rating pair. If part of the compression parameters of the input rate codec has similar quantization approaches and quantization tables as the selected output rate codec, a mixed mode of pass-through and mapping may be a suitable choice for the trans-rating.

The decision can change in a dynamic fashion based on available computational resource or minimum quality requirements. The input rate codec compressed parameters can be mapped in a number of ways giving successively better quality output at the cost of computation complexity. At the highest quality, the computation complexity of the transcoding algorithm is still lower than that of the brute-force tandem approach. Since the four methods trade-off quality for reduced computational load, they can be used to provide graceful degradation in quality in the case of the apparatus being overloaded by a large number of simultaneous channels. Thus the performance of the trans-rating can adapt the available resources.

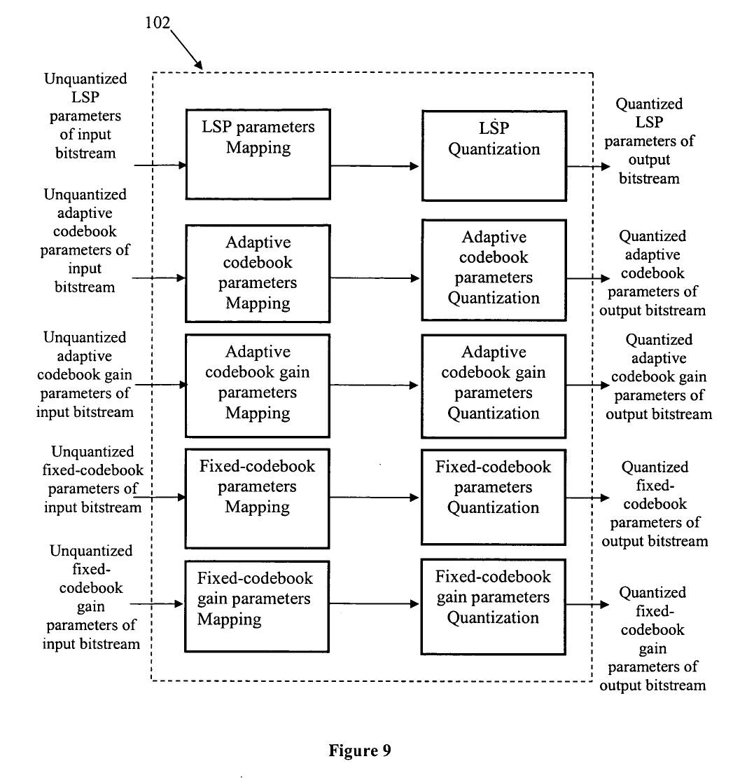

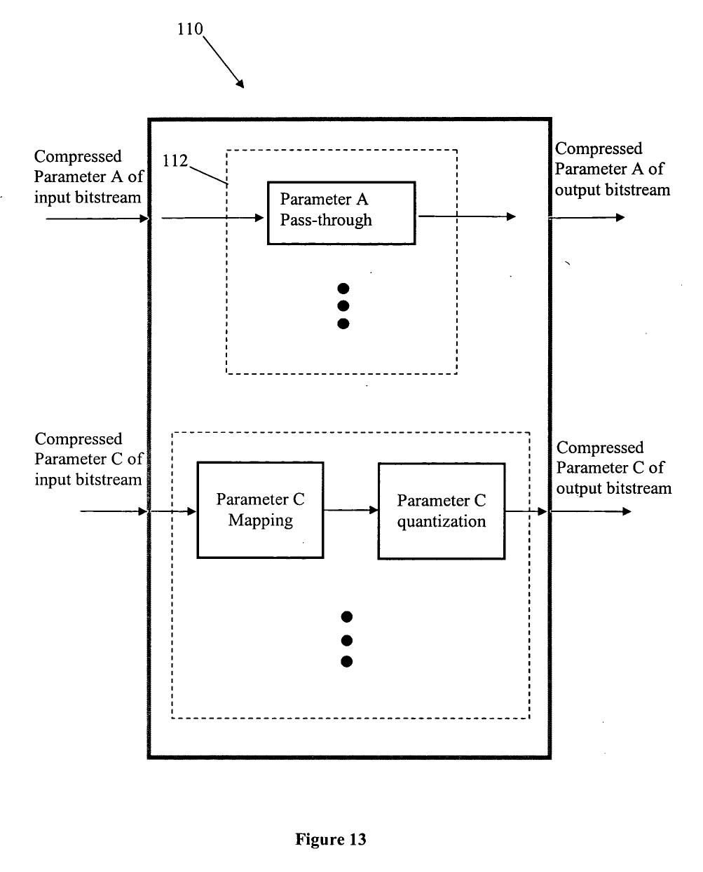

FIGS. 9, 10, 11 and 12 illustrate four different voice compression parameter-based mapping strategies in detail. Beginning with the simplest in FIG. 9, they are presented in order of successive computational complexity and output quality. In addition, FIG. 13 illustrates a method of part pass-through and part mapping. This method is applied to selected compression parameters in the input rate codec and the output rate codec that share the same quantization algorithm and quantization tables. A key feature of the present invention is that voice compression parameters in multi-rate voice coder trans-rating can be mapped directly without the need to reconstruct the speech signals. This means that significant computation is saved during closed-loop codebook searches, since the signals do not need to be filtered by the short-term impulse response, as required by conventional tandem techniques. This mapping works because the input rate bitstream mechanism has previously determined the optimal compressed parameters for generating the speech. The present invention uses this fact to allow rapid pass-through, or direct mapping, or searching, in the excitation domain rather than the full speech domain.

Referring specifically to FIG. 9, there is a block diagram of direct-space-mapping 102. It receives the various unquantized compressed parameters of input rate codec bitstream 104 and performs compressed parameter mapping directly. In a typical CELP codec, it maps LSP parameters, adaptive codebook parameters, adaptive codebook gain parameters, fixed-codebook parameters, and fixed-codebook gain parameters. After each type of parameters mapping, it requantizes these parameters according to output rate codec and sends to next stage of output rate code bistream packing.

Besides pass-through or partial pass-through methods, direct-space-mapping is the simplest trans-rating scheme. The mapping is based on similarities of physical meaning between input rate codec and output rate codec parameters, and the trans-rating is performed directly using analytical formulae without any iteration or extensive searches. The advantage of this scheme is that it does not require a large amount of memory and consumes almost zero MIPS but it can still generate intelligible, albeit degraded quality, sound. This method is generic and applies to all kinds of multi-rate voice coder trans-rating in term of different subframe size or different compressed parameter representation.

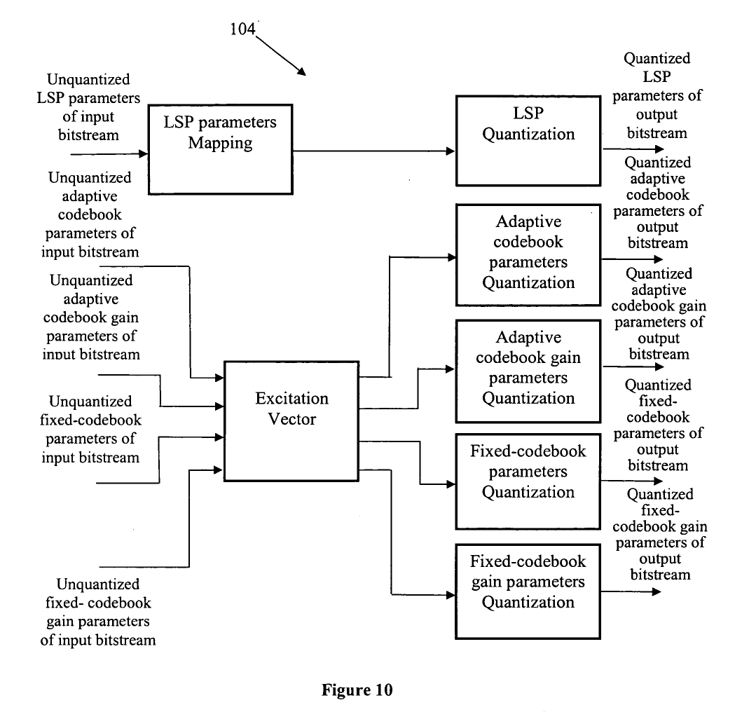

FIG. 10 illustrates a block diagram of analysis in excitation mapping 104. It receives the unquantized LSP parameters from input rate codec bitstream and performs mapping to output rate codec format. Except for the direct-space-mapping method, in which adaptive codebook and fixed-codebook parameters are directly mapped from input bitstream unpacking to the output rate codec format without any searching and iteration, the excitation signal is reconstructed. Reconstruction of the excitation requires the parameters of adaptive codebook, adaptive codebook gains, fixed-codebook, and fixed-codebook gains.

This method is more advanced than the direct-space-mapping method 102 in that the adaptive and fixed codebooks are searched, and the gains are estimated in the usual way defined by the output rate codec, except that they are done in the excitation domain, not the speech domain. The adaptive codebook is determined first by a local search using the unquantized adaptive codebook parameters from the input codec bitstream as the initial estimate. The search is within a small interval of the initial estimate, at the accuracy (integer or fractional pitch) required by the destination codec. The adaptive codebook gain is then determined for the best codeword vector. Once found, the adaptive codeword vector contribution is subtracted from the excitation and the fixed codebook determined by optimal matching to the residual. The advantage over the conventional tandem approach is that the open-loop adaptive codebook estimate does not need to be calculated from an auto-correction method used by the CELP standards, but it can instead be determined from the unquantized parameters of input bitstream. Moreover, the search is performed in the excitation domain, not the speech domain, so that impulse response filtering during adaptive codebook and fixed-codebook searches is not required. This saves a significant amount of computation without any compromising output voice quality.

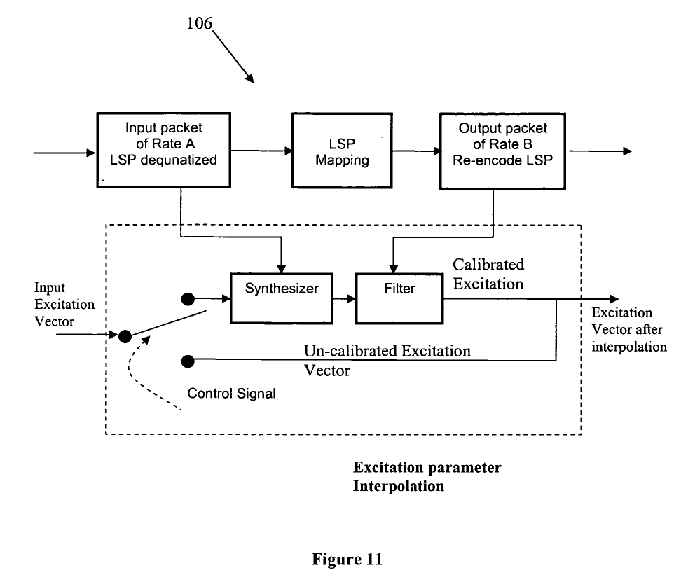

Considering the difference of LSP parameters between input rate codec and output rate codec, the reconstructed excitation can be calibrated in order to compensate the effect of LSP parameters. FIG. 11 depicts the excitation calibration method 106. The reconstructed excitation vector form of input unquantized parameters is synthesized by LPC coefficients of input rate codec to convert to the speech domain, and then filtered using re-quantized LPC parameters of the output rate codec to form the target signal in mapping. This calibration is optional and can significantly improve the perceptual speech quality where there is a marked difference in the LPC parameters between input and output rate codecs.

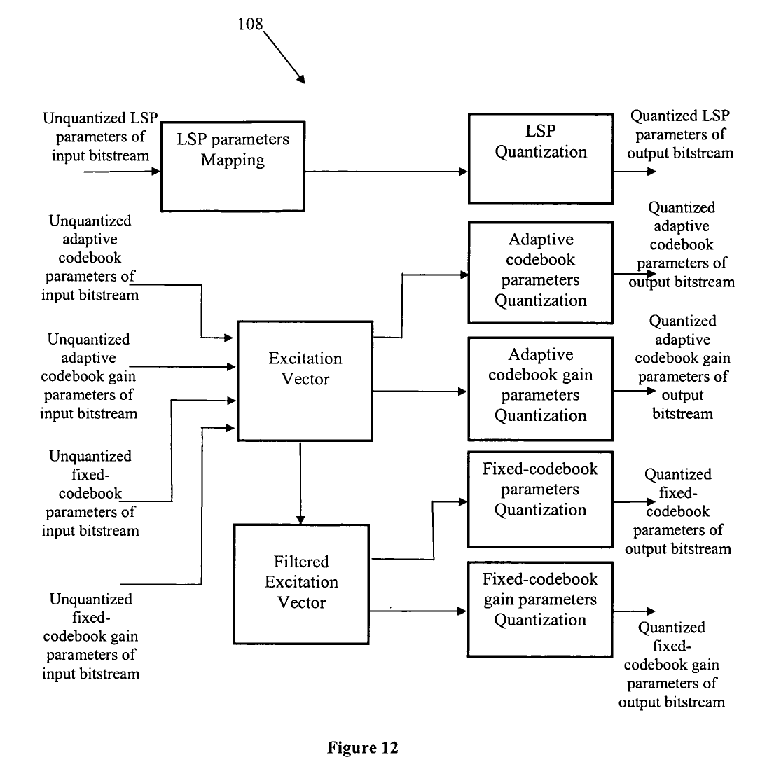

FIG. 12 shows a block diagram of the filtered excitation space direct-space-mapping analysis method 108. In this case, the LPC parameters are still mapped directly from the input rate codec to the output rate code, and the unquantized adaptive codebook parameter is used as the initial estimation for output rate codec. The adaptive codebook search is still performed in the excitation domain or calibrated excitation domain However, the fixed-codebook search is performed in a filtered excitation space domain. Various filters can be applied, including a low-pass filter to smooth any irregularities, a filter that that compensates for differences between characteristic of the excitation vector in the input and output codecs, and a filter which enhances perceptually important signal features. An advantage is that the parameters of the filter (order, frequency emphasis/de-emphasis, phase) are completely tunable. Contrast this with the computation of the target signal in standard encoding, which uses the weighted LP synthesis filter. Hence, this strategy allows for tuning to improve the quality for trans-rating between a particular pair of input and output codecs, as well as the provision for trade-off between quality and complexity.

In some specific trans-rating pairs, the input and output codecs have the same compression algorithm and the same quantization tables in some compression parameters. The above mapping methods can be simplified to portions of pass-through and portions of mapping procedures. FIG. 13 shows a block diagram of a combined pass-through and mapping combination method 110. If some quantized parameters of output rate codec having the same quantization process and quantization tables as those of the input rate codec, the parameters may be directly mapped from input bitstream through the pass-through unit 112 without any searching or quantization procedures. The left quantized parameters of output rate codec may be mapped by one of the mapping methods of direct space mapping, analysis in excitation space mapping and analysis in filtered excitation space mapping.

It is noted that any combinations of the above methods may also be used. The best method to achieve both high quality and low complexity will depend on a balance between the input rate and output rate codecs.

The output rate bitstream packing module connects the trans-rating pair modules or pass-through modules through the configuration control command module 24 (FIG. 5). The packing module groups the converted and quantized parameters of the output rate into output bitstream packets in accordance with the output rate codec.

### First Embodiment

### AMR 5.15 Kbps->4.75 Kbps Trans-Rating

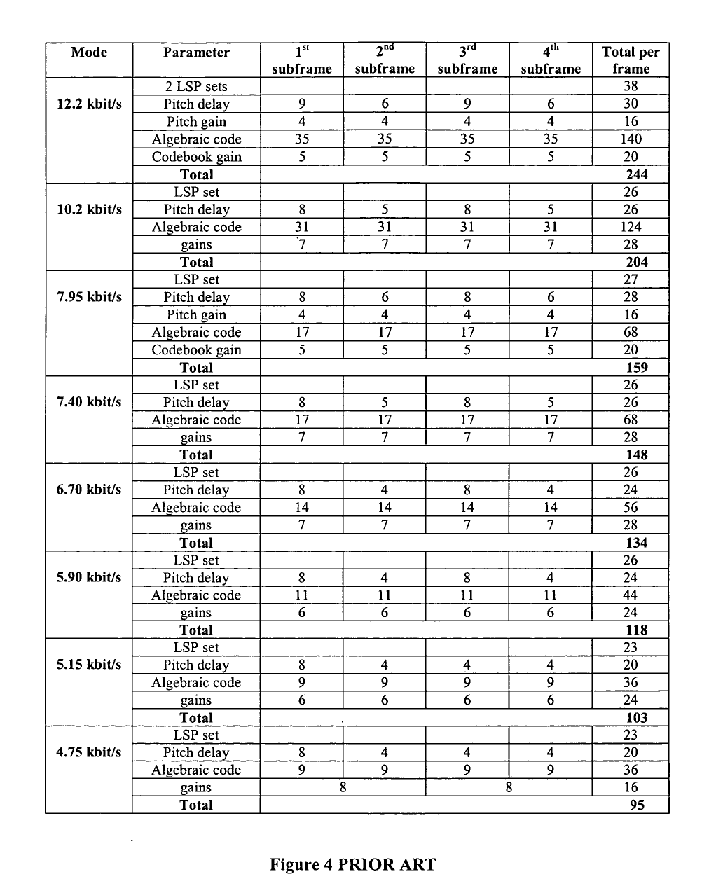

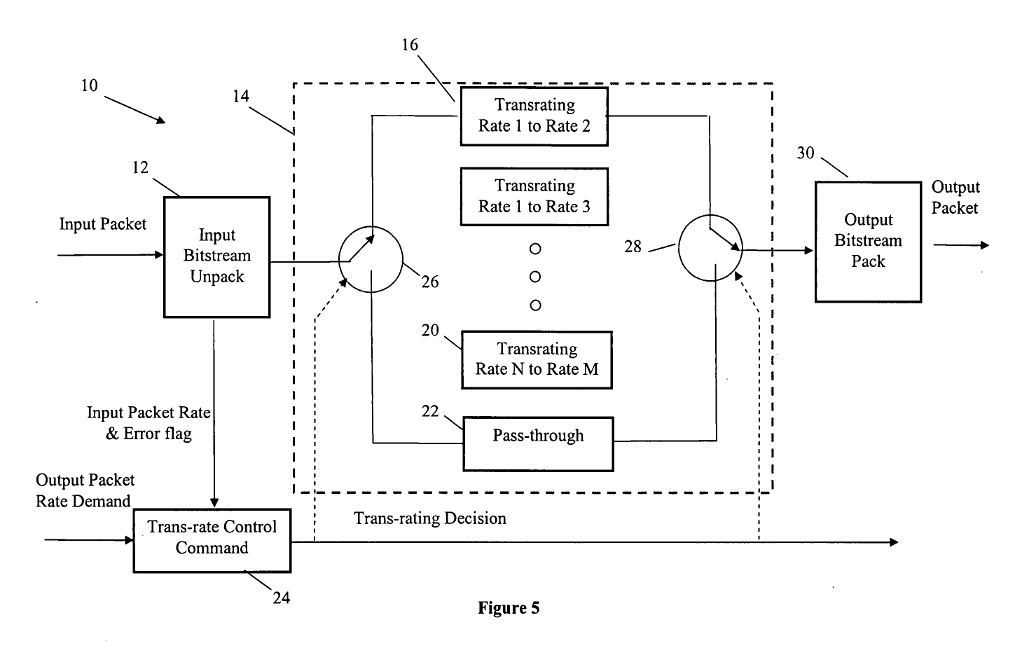

Examples of suitable systems according to the inventions are now described. A multi-rate voice coder (adaptive multi-rate or AMR, also called GSM-AMR) is taken as an example to show the principle of present invention. The AMR codec uses eight source codecs with bit-rates of 12.2, 10.2, 7.95, 7.40, 6.70, 5.90, 5.15 and 4.75 kbps. FIG. 4 shows the bit allocations of 8 bit-rates in AMR coding algorithm.

The codec is based on the CODE-EXCITED LINEAR PREDICTIVE (CELP) coding model. A 10th order linear prediction (LP), or short-term, synthesis filter is used. A long-term, or pitch, synthesis filter is implemented using the so-called adaptive codebook approach.

In the CELP speech synthesis model, the excitation signal at the input of the short-term Linear Prediction (LP) synthesis filter is constructed by adding two excitation vectors from adaptive and fixed (innovative) codebooks. The speech is synthesized by feeding the two properly chosen vectors from these codebooks through the short-term synthesis filter. The optimum excitation sequence in a codebook is chosen using an analysis-by-synthesis search procedure in which the error between the original speech and synthesized speech is minimized according to a perceptually weighted distortion measure. The perceptual weighting filter used in the analysis-by-synthesis search technique uses the unquantized LP parameters.

The coder operates on speech frames of 20 ms corresponding to 160 samples at the sampling frequency of 8,000 sample per second. At each 160 speech samples, the speech signal is analyzed to extract the parameters of the CELP model (LP filter coefficients, adaptive and fixed codebooks' indices and gains). These parameters are encoded and transmitted. At the decoder, these parameters are decoded, and speech is synthesized by filtering the reconstructed excitation signal through the LP synthesis filter.

The GSM-AMR speech frame is divided into 4 subframes of 5 ms each (40 samples). The adaptive and fixed codebook parameters are transmitted every subframe. The quantized and unquantized LP parameters or their interpolated versions are used depending on the subframe. An open-loop pitch lag is estimated in every other subframe (except for the 5.15 and 4.75 kbit/s modes for which it is done once per frame) based on the perceptually weighted speech signal.

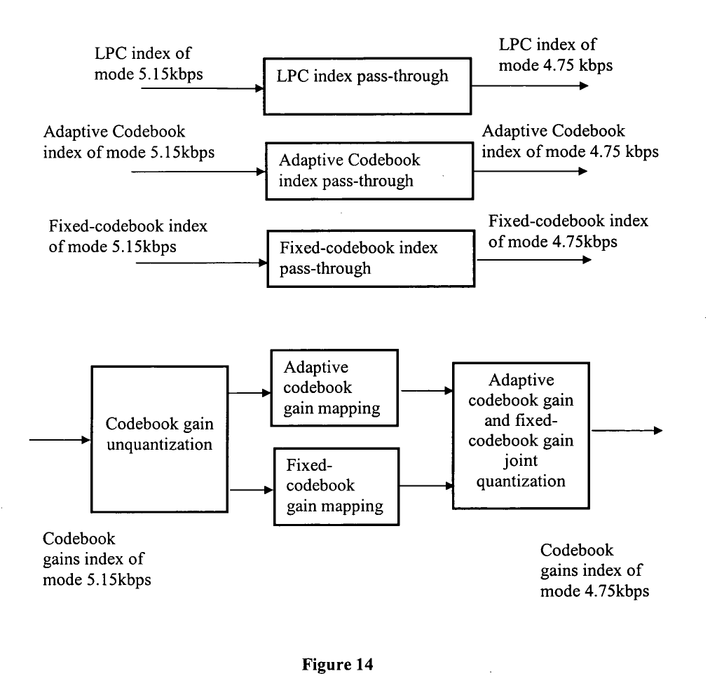

FIG. 14 is a block diagram illustrating part of pass-through and part of direct space mapping mixing method based trans-rating from an AMR 5.15 kbps bitstream to an AMR 4.75 kbps bitstream. The two rates (5.15 and 4.75) share the same Linear Prediction Coefficients (LPC) quantization tables and the same quantization procedures, hence, the indices for the two rates are identical (one to one mapping). Similarly, the two rates share the same adaptive (or pitch) and fixed (or algebraic) codebook index.

In trans-rating between 5.15 and 4.75, these three parameters of Linear Prediction Coefficient (LPC), adaptive codebook parameters and fixed-codebook parameters can be directly mapped from the original bitstream to the destination bitstream without any computation complexity.

In the case of the adaptive codebook gains and fixed-codebook gains, the compression method and tables are different, so the representations of these parameters are different between 5.15 and 4.75 kbps. As shown in FIG. 4, the input AMR 5.15 kbps codec has 6 bits joint gain quantization indices among each subframe, and the output AMR 4.75 kbps codec has 8 bits joint gain quantization indices among every two subframes. The output rate AMR 4.75 kbps requires mapping to convert the 5.15 kbps representation of adaptive codebook gains and fixed-codebook gains to output bitstream format.

A direct space mapping method can be employed to map both adaptive codebook gains and fixed-codebook gains. The input rate joint adaptive codebook and fixed-codebook are initially unquantized. The method obtains the unquantized adaptive codebook gains and fixed-codebook gains every subframe. Then these gains are mapped to each two subframes separately. Finally the adaptive codebook gains and fixed-codebook gains are requantized every two subframes in accordance with the output for the 4.75 kbps codec. The mapping results of joint gain indices of 4.75 kbps are grouped with pass-through results of LSP, adaptive codebook parameters and fixed-codebook parameters together to form the output for the 4.75 kbps bitstream.

It is possible to select analysis in excitation space mapping or analysis in filtered excitation space mapping to search the quantized joint gains of adaptive codebooks and fixed-codebook gains. As both 4.75 kbps and 5.15 kbps have same LPC indices representations, it is not necessary to calibrate the reconstructed excitation vector from the input codec as target signals.

### Second Embodiment

### AMR 4.75 Kbps->5.15 Kbps Transraing

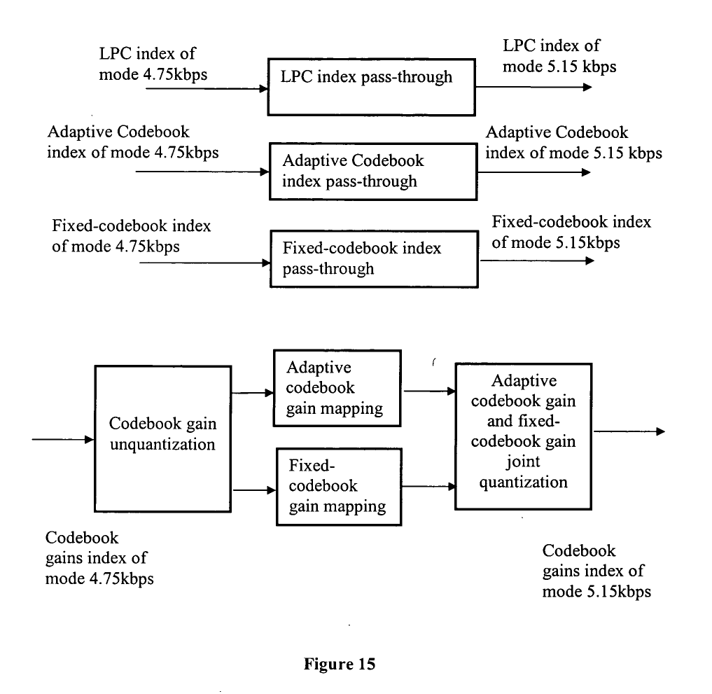

FIG. 15 shows an example of trans-rating an AMR 4.75 kbps bitstream to an AMR 5.15 kbps bitstream according to a second embodiment of present invention. The trans-rating procedure is very similar to that of the opposite direction trans-rating described in the first embodiment. The output codec 5.15 kbps has the same quantization procedures and tables among the LPC coefficients, adaptive codebook parameters, and fixed-codebook parameters. These output unquantized parameters can be obtained directly through the pass-through units in the trans-rating pair.

The joint gain indices of 4.75 kbps can be obtained from unquantization adaptive codebook gains and fixed-codebook gains of 5.15 kbps through one of the mapping methods among direct-space mapping, analysis in excitation space mapping or analysis in filtered excitation space mapping. FIG. 15 shows an approach based on direct-space mapping.

### Third Embodiment

### AMR 12.2 Kbps->4.75 Kbps Transraing

It is important to note that for AMR 12.2 kbps, LP analysis is performed twice per frame and only once for the other modes down to 4.75 kbps. For the 12.2 kbps mode, the two sets of LP parameters are converted to line spectrum pairs (LSP) and jointly quantized using split matrix quantization (SMQ), 38 bits. For the other modes, the single set of LP parameters is converted to line spectrum pairs (LSP) and vector quantized using split vector quantization (SVQ), 23 bits for 4.75 kbps.

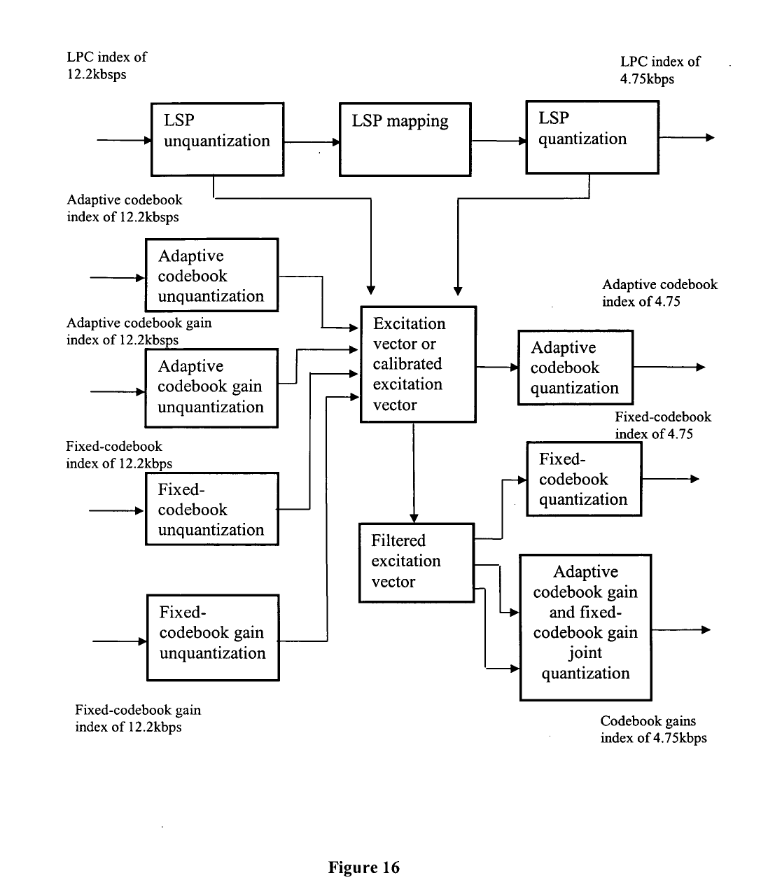

FIG. 16 shows a block diagram of trans-rating from 12.2 kbps to 4.75 kbps according to a third embodiment of the present invention. The trans-rating pair module selects the method of analysis in filtered excitation space mapping to perform rate conversion.

First, the indices of LSF parameters are extracted from the incoming 12.2 kbps bitstream, and then the unquantized LSP parameters are obtained through lookup tables and the previous LSP residual vectors. The unquantized LSP parameters are interpolated and mapped to each subframe. These LSP parameters are re-quantized according to 4.75 kbps codec specified in AMR standard and converted to the LSP representation of 4.75 kbps.

Second, the excitation vector of the input codec 12.2 kbps is reconstructed through unquantized adaptive codebook parameters v[n], adaptive codebook gains ĝₚ, fixed-codebook parameters c[n] and fixed-codebook gains ĝₚ. The reconstructed excitation vector is represented as ĝₚv[n]+ĝₚc[n].

Before the reconstructed excitation vector becomes target signals in trans-rating process, a process of excitation vector calibration may be applied as shown in FIG. 11. The process involves a synthesis step using LPC unquantization parameters of input 12.2 kbps and a filtering step using LPC quantization parameters of output 4.75 kbps. It calibrates the artifacts due to the LSP parameters difference between the 12.2 kbps and 4.75 kbps codecs.

The calibrated excitation vector is then used as the target signals for analysis in excitation space mapping for the output rate 4.75 kbps. The unquantized adaptive codebook parameters of 12.2 kbps as an initial estimate in the closed-loop adaptive codebook search of 4.75 kbps. This search obtains the quantized adaptive codebook parameters and adaptive codebook gains. As the 4.75 kbps codec uses joint gain indices to represent the adaptive codebook and fixed-codebook gains, the quantization of adaptive codebook gain of 4.75 kbps is performed after fixed-codebook searching.

The adaptive codeword vector contribution is removed from the calibrated excitation. The result is filtered using a filter to produce the target signal for the fixed codebook search. The fixed codebook vector of 4.75 kbps consists of two pulses forming the codeword vector is then searched by a fast technique. Thus, the fixed-codebook index of 4.75 kbps is obtained.

Unlike, 12.2 kbps codec, 4.75 kbps combines a joint search for both the adaptive codebook gain (ĝₚ) and fixed codebook gain (ĝₚ). Using the computed adaptive codeword vector v[n], along with the fixed codebook vector c[n], a dual search on the pitch gain and the fixed codebook gain is performed to minimize the relation ∥x−gₚv−g_{c}∥, where x is the target excitation. The common table index for the adaptive and fixed codebook is coded in the first and third subframe of the 4.75 kbps.

As mentioned previously, the other two methods, direct space mapping or analysis in excitation space mapping may be applied to the trans-rating from 12.2 kbps to 4.75 kbps. These different methods trade-off quality for reduced computational load, they can be used to provide a graceful degradation in quality in the case of the apparatus being overloaded by a large number of simultaneous channels.

### Fourth Embodiment

### AMR 4.75 Kbps->12.2 Kbps Transraing

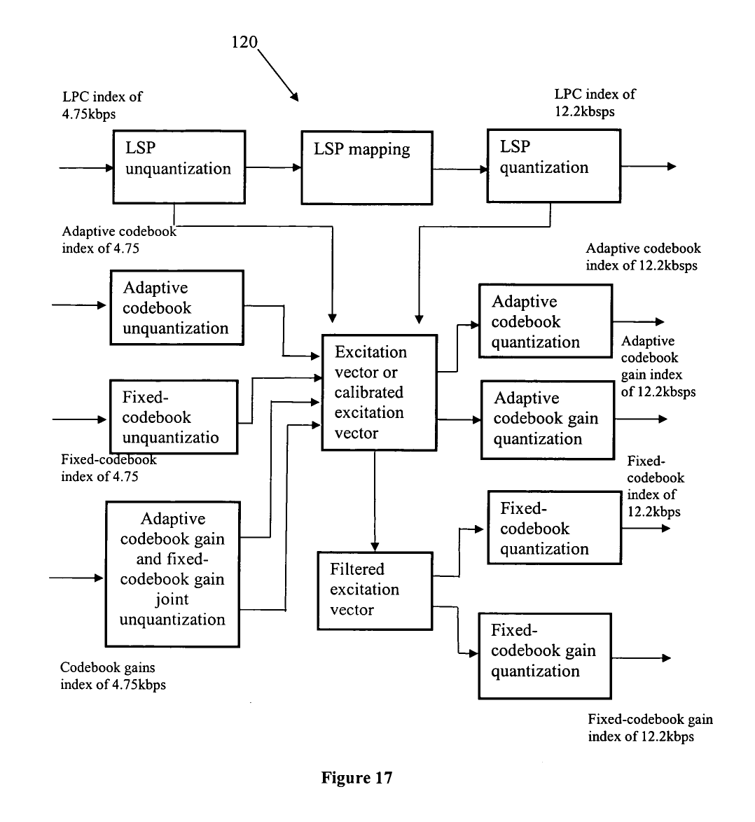

FIG. 17 shows a block diagram of a system 120 for trans-rating from 4.75 kbps to 12.2 kbps according to a fourth embodiment of present invention. The trans-rating selects analysis in filtered excitation space mapping method to convert 4.75 kbps to 12.2 kbps.

First, the indices of LSF parameters are extracted from the incoming 4.75 kbit/s bitstream, and then the unquantized LSP parameters are obtained through lookup tables and the previous LSP residual vectors. The unquantized LSP parameters are interpolated and mapped to each subframe. These LSP parameters are re-quantized every two subframes according to the 12.2 kbps codec as specified in AMR standard and converted to the LSP representation of 12.2 kbps.

Second, the excitation vector of input codec 4.75 kbps is reconstructed through unquantized adaptive codebook parameters v[n], adaptive codebook gains ĝₚ, fixed-codebook parameters c[n] and fixed-codebook gains ĝₚ. The reconstructed excitation vector is represented as ĝₚv[n]+ĝₚc[n].

Before the reconstructed excitation vector becomes target signals in trans-rating process, a process of excitation vector calibration may be applied as shown in FIG. 11. The process involves a synthesis step using LPC unquantization parameters of input 4.75 kbps and a filtering step using LPC quantization parameters of output 12.2 kbps. It calibrates the artifacts due to the LSP differences between the 4.75 kbps and 12.2 kbps codecs.

The calibrated excitation vector is then used as the target signals for analysis in excitation space mapping for the output rate of 12.2 kbps. The unquantized adaptive codebook parameters of 4.75 kbps as an initial estimate in the closed-loop adaptive codebook search of 12.2 kbps. The adaptive codebook is searched within a small interval of the initial estimate, at the accuracy of ⅙ required by the 12.2 kbps codec. The adaptive codebook gain is then determined for the best code-vector and the adaptive code-vector contribution is removed from the calibrated excitation. The result is filtered using a filter to produce the target signal for the fixed-codebook search.

The fixed-codebook is then searched in the filtered excitation space by a fast technique to obtain indices to form a 10 pulse codeword vector according to the 12.2 kbps codec. Also the filtered excitation space is used to compute the fixed-codebook gain of the 12.2 kbps codec.

The trans-rating from 4.75 kbps to 12.2 kbps can also employ the other noted mapping methods. This allows the trans-rating to adapt to the available computation resources in real-time applications.

Other CELP Transcoders

The invention of adaptive codebook computation described in this document is generic to all multi-rate voice coders and applies to any voice trans-rating in known multi-rate voice codecs such as G.723.1, G.728, AMR, EVRC, QCELP, MPEG-4 CELP, SMV, AMR-WB, VMR and all other future CELP-based voice codecs that make use of multi-rate coding.

The invention has been explained with reference to specific embodiment to enable any person skilled in the art to make or use the invention. Various modifications will be apparent to those skilled in the art, and the generic principles defined herein may be applied to other embodiments without the use of the inventive faculty. Thus, the present invention is not intended to be limited to the embodiments shown herein but is to be accorded with the widest scope consistent with the principles and novel features disclosed herein as indicated by the claims.

1. An apparatus for performing voice trans-rating from a first source bitstream representing frames of data encoded according to a first rate-based mode of a voice compression standard to a second destination bitstream representing frames of data encoded according to a second rate-based mode of a second voice compression standard comprising:
a source bitstream unpacker for separating voice code from the first bitstream at an input data rate into separate codes representing speech parameters;
a trans-rating controller module operative on the first bitstream to output a desired bitstream data rate mode, and operative on an external control command to output a decision on output data rate;
a plurality of pairs of trans-rating modules for trans-rating input bitstream data, said trans-rating modules operative to receive input on speech parameters of input data rate generating from the source bitstream unpacker and operative to output quantized speech parameters of an output data rate;
a pass-through module operative to pass an input coded index directly to output; and
a destination bitstream packer for grouping the output quantized speech parameters at the output data rate into destination bitstream packets.

2. The apparatus of claim 1 wherein the source bitstream unpacker comprises:
a bitstream data rate identifier that receives input from a bitstream frame of data encoded at a data rate according to a voice compression standard and outputs the data rate of the packet; and
a source bitstream payload data unquantizer that dequantizes the codes of speech compression parameters.

3. The apparatus of claim 1 wherein the source bitstream unpacker is a plurality of parallel modules.

4. The apparatus of claim 1 wherein the trans-rating controller module comprises:
a parameter buffer operative to store the input rate and output rate of a preceding frame, an error-flag of the preceding frame, and an external command of a plurality of preceding frames; and
a decision module operative to accept external control commands to input data rate a previous frame output data rate in order to output a final decision of trans-rating.

5. The apparatus of claim 1 wherein said the trans-rating controller module is a plurality of modules.

6. The apparatus of claim 1 wherein one of said trans-rating modules comprises:
a decision module, the decision module being adapted to select a Code Excited Linear Prediction parameter mapping strategy based upon a plurality of strategies;
a module for voice compression parameters direct space mapping operative to produce the destination data rate compression parameters using analytical formulae without iteration;
a module for analysis in excitation space domain mapping operative to produce the destination data rate compression parameters by searching in excitation space domain;
a module for analysis in filtered excitation space domain mapping operative to produce the destination data rate compression parameters by searching via adaptive closed-loop in excitation space and via fixed-codebook in filtered excitation space;
a module for pass-through mixed mapping that mixes part of quantized parameter pass-through where a portion of parameters of input data rate bitstream have quantized values identical to parameters of the output data rate bitstream.

7. The apparatus of claim 1 wherein said the multi-rate pairs trans-rating module is a plurality of modules.

8. The apparatus of claim 1 wherein said the pass-through module is a single plurality of modules.

9. The apparatus of claim 1 wherein said the destination codec packer comprises of a plurality of frame packing elements, each of the frame packing elements being operative to adapt to a pre-selected data rate from a multi-rate voice compression coder.

10. The apparatus of claim 1 wherein said the voice compression standard is a multi-rate/multi-mode codec which contains in its bitstream information regarding data rate, pitch gains, fixed codebook gains and spectral shape parameters including Line Spectral Frequencies.

11. The apparatus of claim 2 wherein the source bitstream payload data unquantizer comprises:
a code separator, the code separator operative to receive input from a bitstream frame of data encoded at a data rate according to a voice compression standard and to separate the index representing speech compression parameters;
at least one dequantizer module operative to dequantize codes of each compression parameter; and
a code index pass-through module operative to pass input quantized parameters indices to following stages.

12. The apparatus of claim 6 wherein said voice compression parameters direct space mapping module comprises:
an LSP coefficient converter operative to encode destination rate LSP coefficients;
an adaptive codebook parameter converter operative to encode destination rate adaptive codebook parameters;
an adaptive codebook gain parameter converter operative to encode destination rate adaptive codebook gain parameters;
a fixed-codebook parameter converter operative to encode destination rate fixed-codebook parameters; and
a fixed-codebook gain parameter converter operative to encodes destination rate fixed-codebook gain parameters.

13. The apparatus of claim 6 wherein said analysis in excitation space domain mapping module comprises:
an LSP coefficient converter operative to encode destination rate LSP coefficients;
an excitation vector module operative to construct excitation parameters from input compressed speech parameters;
an adaptive codebook parameter converter operative to encode destination rate adaptive codebook parameters by performing a first search in excitation space;
an adaptive codebook gain parameter converter operative to encode the destination rate adaptive codebook gain parameters by performing a second search in excitation space;
a fixed-codebook parameter converter operative to encodes the destination rate fixed-codebook parameters by performing a third search in excitation space; and
a fixed-codebook gain parameter converter operative to encode the destination rate fixed-codebook parameters by performing a fourth search in excitation space.

14. The apparatus of claim 6 wherein said module for analysis in filtered excitation space domain mapping module comprises:
an LSP coefficient converter operative to encode the destination rate LSP coefficients;
an excitation vector module operative to construct the excitation parameters from the input compressed speech parameters;
a filtered excitation vector module operative to construct the filtered excitation parameters from input compressed speech parameters and the excitation vector module;
an adaptive codebook parameter converter operative to encode the destination rate adaptive codebook parameters by performing a search in excitation space;
an adaptive codebook gain parameter converter operative to encode the destination rate adaptive codebook gain parameters by performing a search in at least one of excitation space and filtered excitation space;
a fixed-codebook parameter converter operative to encode the destination rate fixed-codebook parameters by performing a search in filtered excitation space; and
a fixed-codebook gain parameter converter operative to encode the destination rate fixed-codebook parameters by performing a search in filtered excitation space.

15. The apparatus of claim 6 wherein said the pass-through mixed mapping module comprises:
a parameter pass-through module operative to pass part of input encoded compressed speech parameters to the destination rate encoded compressed speech parameters; and
a parameter converter module operative to encode the destination rate compressed speech parameter from input compressed speech parameters.

16. The apparatus of claims 13 wherein said excitation vector module further comprises:
an input rate codec excitation buffer operative to store the reconstructed excitation vector based upon the input rate codec at least for one Code Excited Linear Prediction parameter;
an excitation vector calibration unit operative to calibrate the input excitation vector by using an input rate codec quantized LPC coefficients and output rate code encoded LPC coefficients; and
a calibrated excitation buffer operative to store the calibrated excitation vector used for target in the output rate codec encoding process.

17. The apparatus of claim 15 wherein the parameter pass-through module is a plurality of modules.

18. The apparatus of claim 15 wherein said the parameter converter module is a plurality of modules.

19. The apparatus of claim 15 wherein said the parameter converter module is part of at least one of the voice compression parameters direct space mapping module, the analysis in excitation space domain mapping module, and the analysis in excitation space domain mapping module.

20. A method for converting a voice compression packet from a first source bitstream representing frames of data encoded according to a first rate-based mode of a first voice compression standard in a source codec to a second destination bitstream representing frames of data encoded according to a second rate-based mode of a second voice compression standard in an output rate codec comprising:
processing a header of a source codec input bitstream to identify characteristics of the data stream including at least one of data rate, mode, and packet type of the input bitstream;
processing the source codec input bitstream to unpack at least one parameter from the input bitstream;
configuring a trans-rating pair to convert the input bitstream at an identified input rate to output the destination bitstream at a demanded output rate;
converting input of the at least one encoded parameter of the identified input rate to generate as output at least one corresponding parameter of the demanded output rate;
passing through at least one encoded parameter to the output rate codec if quantization of the encoded parameter is the same as is employed at the output rate codec; and
processing the output bitstream by packing at least one parameter for the output rate codec.

21. The method of claim 20 wherein the source codec input processing step comprises:
converting an input bitstream frame into information associated with at least one Code Excited Linear Prediction parameter;
decoding the associated information into at least one of the input bitstream, the input bitstream being a Code Excited Linear Prediction bitstream; and
outputting Code Excited Linear Prediction parameters to an interpolator.

22. The method of claim 21 wherein the transrating pair configuring step comprises:
extracting source information about at least one of input rate and mode from a header of the input Code Excited Linear Prediction bitstream;
retrieving at least one of an external control command and the demanded rate out of the output bitstream, the output bitstream being a Code Excited Linear Prediction bitstream;
checking previous trans-rating status; and
outputting a trans-rating pair selection decision.

23. The method of claim 20 wherein the converting step is selected from one of a plurality of conversion methods, comprising:
direct Code Excited Linear Prediction parameters space mapping;
analysis in excitation space domain mapping;
analysis in filtered excitation space mapping; and
part of pass-though and part of parameters mapping.

24. The method of claim 20 wherein the trans-rating pair configuring step is for a predetermined application selected during a preliminary process.

25. The method of claim 20 wherein the conversion methods further include an interpolation step if there exists a difference between subframe size of the demanded output rate codec format and subframe size of the input rate codec format.

26. The method of claim 20 wherein the passing through step comprises conveying the encoded parameters of input rate codec from bitstream unpacker to the encoded parameters of output rate codec.

27. The method of claim 21 wherein the Code Excited Linear Prediction destination rate codec bitstream processing step comprises a plurality of frame packing subprocessing steps, each of the subprocessing steps being capable of adapting to a pre-selected application from a plurality of applications for a selected destination rate codec, the selected destination rate codec being one of a plurality of multi-rate codecs.

28. The method of claim 23 wherein the direct Code Excited Linear Prediction parameters space mapping step comprises of the following steps:
converting at least one LSP coefficient from the input rate codec to at least one or LSP coefficient for the output rate codec;
encoding adaptive codebook parameters from the input rate codec adaptive codebook parameters;
encoding the adaptive codebook gain parameters from the input rate codec adaptive codebook gain parameters;
encoding fixed-codebook parameters from the input rate codec fixed-codebook parameters; and
encoding the fixed-codebook gain parameters from input rate codec fixed-codebook gain parameters.

29. The method of claim 23 wherein the excitation space domain mapping analysis step comprises of the following steps:
converting at least one LSP coefficient from the input rate codec to at least one LSP coefficient for the output rate codec;
calibrating an input rate codec excitation vector as a target vector for mapping if a calibration option is selected;
selecting adaptive codebook parameters from input rate codec adaptive codebook parameters as initial values;
searching the adaptive codebook parameters in closed-loop in excitation space;
searching adaptive codebook gain in excitation space;
constructing a target signal for fixed-codebook search;
searching fixed codebook parameter in filtered excitation space;
searching fixed codebook gain in filtered excitation space; and thereupon updating the excitation vector with updated parameters as an input rate codec reconstructed excitation vector.

30. The method of claim 23 wherein the filtered excitation space domain mapping analysis step comprises the steps of:
converting at least one input rate codec LSP coefficient from the input rate codec to at least one output rate codec LSP coefficient for the output rate codec;
calibrating the input rate codec excitation vector as a target vector for mapping if the calibration option is selected;
selecting an adaptive codebook parameter from input rate codec adaptive codebook parameters as an initial value;
searching an adaptive codebook in closed-loop in excitation space;
searching adaptive codebook gain in excitation space;
constructing a target signal representation for a fixed-codebook search;
searching fixed codebook parameter in filtered excitation space;
searching fixed codebook gain in filtered excitation space; and
updating the excitation vector with updated parameters.

31. The method of claim 23 wherein a portion of the pass-through step and a portion of the parameters mapping step comprises the steps of:
classifying the input rate codec parameters into a pass-through class and a mapping class, the input rate codec parameters having in common encoding methods and index in the input rate codec, and the output rate codec being classified as a pass-through class, and all other input rate codec parameters being classified as mapping class;
passing through the pass-through-class parameters of the input rate codec to the parameters of output rate codec; and
converting the mapping-class parameters of the input rate codec to corresponding parameters of the output rate codec by using at least one of a direct Code Excited Linear Prediction parameters space mapping method, an excitation space domain mapping analysis method, and a filtered excitation space mapping analysis method.

32. The method of claim 23 wherein said conversion methods are combined as a combination method.

33. The method of claim 23 wherein the conversion method in a specific trans-rating pair is selected dynamically.

34. The method of claim 25 wherein the interpolation step comprises:
interpolating at least one of the LSP coefficients from the input rate codec to corresponding LSP coefficients for the output rate codec;
interpolating Code Excited Linear Prediction parameters other than the LSP coefficients from the input rate codec to corresponding Code Excited Linear Prediction parameters for the output rate codec.

35. The method of claim 29 wherein said the calibrating excitation vector calibrating step further comprises:
converting the input rate codec reconstructed excitation vector to a synthesized speech vector by using at least one of the input rate codec decoded LPC coefficients;
converting the synthesized speech vector back to calibrated excitation vector by using at least the quantized output rate codec LPC coefficients; and
transferring the calibrated excitation vector for target signals for excitation space mapping analysis in and filtered excitation space mapping analysis.

36. The method of claim 33 wherein the control signal is provided based upon a computing resource characteristic of the selected trans-rating mapping strategy.

37. The method of claim 33 further comprising:
receiving the control signal at a switching module, the switching module being coupled to each of a plurality of elements operative to perform the mapping strategies.

38. The method of claim 33 wherein at least one of the plurality of mapping strategies is provided from a library in memory.

39. The method of claim 34 further comprising converting at least one of the LSP coefficients using a linear transform process.

40. The apparatus as in claim 1 further including an element for changing the trans-rating strategy to thereby provide a mechanism to adapt to available computational resources and allow for graceful quality degradation under load.

41. The apparatus as in claim 1 further including a silence frame transcoding unit operative to perform at least one of rapid conversion of silence frames from input rate active speech format to output silence frames and of rapid conversion of silence frames from input silence frames to output desired rate active speech frames, including mapping of the comfort noise parameters.

42. The apparatus as in claim 1 further including an element for excitation mapping operative to be performed without reverting back to the speech signal domain.
